(19) United States
(12) Patent Application Publication
(10) Pub. No.: US 2024/0176356 A1
(43) Pub. Date: May 30, 2024

(54) METHOD FOR ESTABLISHING A MAP OF A PARAMETER IN AN AREA BASED ON A SENSOR MOUNTED ON AN AUTONOMOUS ROBOT

(71) Applicant: Orange, Issy-les-Moulineaux (FR)

(72) Inventors: Loïc AVENEL, CHATILLON CEDEX (FR); Régis ESNAULT, CHATILLON CEDEX (FR)

(21) Appl. No.: 18/509,202

(22) Filed: Nov. 14, 2023

(30) Foreign Application Priority Data
Nov. 25, 2022 (FR) 2212343

(51) Int. Cl. G05D 1/02; A47L 11/40

(52) U.S. Cl. CPC G05D 1/0274; A47L 11/4011; G05D 1/0238; G05D 1/0272; A47L 2201/04; G05D 2201/0215

(57) ABSTRACT

A method of obtaining measurement data for at least one parameter, based on at least one sensor, where the sensor is mounted on a robot type of device capable of moving about within an area in order to carry out a first function. The method includes: activating the sensor in order to measure the parameter at least during a movement of the device within the area, and acquiring data, in a second function of the device that is distinct from the first function, in order to establish a map of the parameter in the area.

### CROSS-REFERENCE TO RELATED APPLICATIONS

This application claims foreign priority to French Patent Application No. 2212343, entitled “METHOD FOR ESTABLISHING A MAP OF A PARAMETER IN AN AREA BASED ON A SENSOR MOUNTED ON AN AUTONOMOUS ROBOT” and filed Nov. 25, 2022, the content of which is incorporated by reference in its entirety.

### BACKGROUND

### Technical Field

This disclosure falls within the field of parameter mapping.

More particularly, this disclosure relates to a method for establishing a map of a parameter in an area, based on a sensor mounted on an autonomous robot.

### Prior Art

Mapping the strength of a wifi signal propagated in a defined area can be useful, for example for improving the strength of the wifi signal or in order to find the best place to install a wifi repeater.

To establish a map of the wifi signal strength, tools such as a wifi sensor and a digital control interface are required. The area to be mapped must be visited by a technician who has knowledge of these tools, in order to extract an accurate map of the wifi signal strength.

More generally, establishing a map of the strength of a signal coming from a system such as a heating or ventilation system, or a wifi transmitter in an indoor or outdoor area, requires the use of specific tools and the involvement of a technician having specific knowledge of these tools.

Regular measurements may be necessary, for example to analyze the evolution of the signal over time or the impact of a variable on the signal strength.

For example, in the case of a wifi signal, measurements can be made in a room as a function of the position of a given object present in the area, or as a function of time.

The known mapping methods present disadvantages.

In particular, regular service calls by a technician having knowledge of the mapping tools to be used are necessary. These service calls must be repeated in order to update the map and to understand the impact of different variables on the strength of the signal.

A plurality of tools is required, according to the type of signal and the type of map to be established.

There is therefore a need for an effective method for establishing a map of the strength of a signal, without the involvement of a technician being necessary and without requiring the use of a plurality of tools.

### SUMMARY

To this end, a method is disclosed for obtaining measurement data for at least one parameter, based on at least one sensor, wherein said sensor is mounted on a robot type of device capable of moving within an area in order to carry out a first function, the method comprising:
activating the sensor in order to measure the parameter at least during a movement of the device within the area, and
acquiring data, in a second function of the device that is distinct from the first function, in order to establish a map of said parameter in the area.

The method makes it possible to establish a map of the parameter in the area.

The method aims to provide a response to the disadvantages cited above and to propose the obtaining of measurement data for a parameter without the use and movement of an individual device being required for this purpose. A device capable of performing a first function is used, for example a vacuum cleaner which moves autonomously in order to clean a building. The device can map the area while it is performing the first function.

The proposed method is innovative in using a device having a first function that is distinct from the second function, to establish a map of an area.

Moreover, the method is original, in that it allows establishing a map autonomously and without the use of tools designed for a particular type of signal being necessary. The involvement of a technician is not required and the method can be implemented by a person who does not have specific knowledge relating to the device.

The method is part of a sustainable development strategy, as an already existing device is used and an additional device is not required for establishing the map.

An area can be traveled regularly by the device, which allows updating the map, studying the map's evolution over time, and analyzing the impact of a variable on the map.

In an embodiment, the sensor is activated to measure the parameter while the device is moving about within the area to carry out said first function.

The sensor may be activated only when a map of the parameter is to be established in the area, thus reducing the energy consumed by the device and in particular by the sensor.

In an embodiment, the parameter is one among: at least one wifi signal strength, a temperature, a humidity level, a pressure, and a light intensity.

Mapping the wifi signal strength can make it possible to optimize the location where a wifi gateway, a home Internet hub, or a repeater are installed. Objects present in an area can be moved according to the map, in order to optimize the wifi signal strength at a given location in the area.

Mapping the temperature in a building can allow detecting and optimizing faulty insulation in walls or windows, or optimizing the use of heating.

Mapping the level of humidity in an area can make it possible to find an optimal physical storage location for the device, in order to preserve its service life for example.

Mapping the pressure may allow detecting the occurrence of events causing a variation of pressure in an area. For example, it may be determined whether a window has been opened or not.

Mapping the light intensity in an area may allow detecting the occurrence of events causing a change in light intensity in the area. For example, it may be possible to determine whether a light bulb has been turned on or off.

In an embodiment, the acquisition of data in order to establish the map of the parameter uses topology data for the area from a previously saved digital map corresponding to a topology of the area.

Prior knowledge of the topology of the area to be mapped, and in particular knowledge of the obstacles present in the area, enables the device to move more efficiently and quickly within the area.

Comparison of a current map to maps previously established for the same area is facilitated.

In an embodiment, the method comprises a measurement of topology data for the area by determining distances traveled by the device between obstacles present in the area, in order to obtain a digital map of the area.

No prior knowledge of the area is required. For example, the topology can be determined by means of measurements of angular distances traveled by the wheels of a vacuum cleaner or a mower, from one obstacle to another, or the flight time between two obstacles in the case of a drone.

The use of an additional device to determine the topology of the area is not necessary, and an already available device is used for this purpose.

In an embodiment, the device is reprogrammed to use the topology data for the area, for the purposes of a new function in the implementation of the first function.

Implementation of the first function can thus be optimized by the use of topology data.

For example, mapping the humidity level in an area can make it possible to find an optimal physical storage location for the device, in order to preserve its service life.

In an embodiment, at least two sensors are mounted on the robot type of device, the method comprising:
activating a first sensor mounted on the robot type of device for measuring a first parameter at a given location of the robot type of device during a predetermined time interval;
activating a second sensor distinct from the first sensor and mounted on the robot type of device for measuring a second parameter at said location of the robot type of device during said predetermined time interval;
iterating the measurement of the first parameter and the second parameter, and determining an occurrence of an event or an absence of said event in the area, based on the measurements of the first parameter and the second parameter.

The duration of the time interval may be chosen in dependence on the intended application.

The use of at least two sensors allows identifying phenomena that cannot be identified with only one sensor.

For example, a device can comprise a temperature sensor and a pressure sensor. When the temperature sensor detects a temperature decrease in the area, the pressure sensor may be used to determine the origin of the temperature decrease. Thus, it is possible to distinguish for example between the opening of a window (causing a variation in pressure) and the adjustment of a heater.

In an embodiment, at least three sensors are mounted on the robot type of device, the method further comprising:
activating a third sensor distinct from the first sensor and the second sensor and mounted on the robot type of device for measuring a third parameter at said location of the robot type of device during said predetermined time interval;
iterating the measurement of the first parameter, the second parameter and the third parameter, and determining an occurrence of an event or an absence of said event in the area, based on the measurements of the first parameter, the second parameter and the third parameter.

The duration of the time interval may be chosen in dependence on the intended application.

The use of at least three sensors allows identifying phenomena that cannot be identified with one or two sensors.

For example, the first sensor may be a temperature sensor, the second sensor may be a humidity sensor and the third sensor may be a light sensor. When the temperature sensor detects a temperature decrease in an area, the humidity sensor and the light sensor may be used to determine the origin of the temperature decrease.

Thus, it is possible to distinguish for example between the opening of the door of a refrigerator illuminated from the inside (causing an increase of the humidity level and of the light intensity in the zone) and the opening of a window.

Another aspect of this disclosure concerns a computer program product comprising instructions which, when these instructions are executed by a processing circuit, cause the processing circuit to implement the aforementioned method.

This program can use any programming language (for example, an object-oriented language or other), and be in the form of interpretable source code, partially compiled code, or fully compiled code.

FIG. 4 described in detail below can serve as the flowchart for the general algorithm of such a computer program.

Another aspect of this disclosure concerns a robot type of device, capable of moving within an area in order to carry out a first function, to obtain measurement data for at least one parameter, the device comprising a processing circuit configured to implement the aforementioned method.

The processing circuit already present in the device can be used for implementing the method, minimizing the number of additional tools required for implementing the method, for a sustainable development.

In an embodiment, the device further comprises an expansion module connected to the processing circuit and comprising:
at least one sensor configured to be activated and to measure the parameter at least during a movement of the device within the area;
an acquisition interface configured to acquire data, according to the second function of the device, in order to establish a map of said parameter in the area.

Thus, an already available device can be used without major modifications being necessary to the device. A given expansion module can be used in combination with different types of autonomous devices.

For example, the same expansion module can be used on a vacuum cleaner, on a mower, and on a drone, in order to avoid a proliferation of sensors and the installation of a sensor in each of the devices used.

It is possible for the sensor to be activated only when a map of the parameter is to be established in the area, thus reducing the energy consumed by the device.

In an embodiment, the expansion module further comprises a position sensor configured to determine a location of the device when moving about within the area.

Thus, it is not necessary to integrate a position sensor into each of the autonomous devices used by a user.

A mower, a vacuum cleaner, and a drone without a position sensor can be used, and can take advantage of the position sensor of the expansion module.

According to another aspect, an expansion module is also described which is configured to be connected to a processing circuit of a device able to move about within an area in order to carry out a first function, the expansion module comprising:
a connection interface configured to connect the expansion module to the processing circuit of the device;
at least one sensor configured to be activated and to measure at least one parameter during a movement of the device within the area;
an acquisition interface configured to acquire data, according to a second function of the device that is distinct from the first function, in order to establish a map of said parameter in the area.

The expansion module can be used in combination with any type of device that has a reception interface suitable for receiving the connection interface.

In an embodiment, the data acquisition interface is connected to a remote server and is configured to transmit the acquired data to the remote server.

The mapping may be analyzed remotely, by a provider of the device or by a provider of a signal for which a parameter has been measured, and a diagnosis can be established.

For example, the map of the wifi signal strength can be analyzed by a mobile network operator which is providing the wifi signal to a user. The operator can then, depending on the result of the diagnostics, advise the user and indicate the best location for installing the home Internet hub or repeater.

In an embodiment, the data acquisition interface is connected to the processing circuit of the device in order to send mapping data for said parameter to said processing circuit, the processing circuit being programmed to be configured to use the mapping data in performing the first function.

Implementation of the first function by the device can thus be optimized by the use of mapping data.

For example, mapping the level of humidity in an area can make it possible to find an optimal physical storage location for the device, in order to preserve its service life.

### BRIEF DESCRIPTION OF DRAWINGS

Other features, details, and advantages will become apparent upon reading the detailed description below, and upon analyzing the attached drawings, in which:

FIG. 1a and FIG. 1b schematically represent two embodiments of a vacuum cleaner capable of moving autonomously within an area in order to establish a map of a parameter.

FIG. 2 represents a flowchart of a method for obtaining measurement data for a parameter, based on a sensor mounted on a vacuum cleaner, in order to establish a map of the area.

FIG. 3 schematically represents a map of the strength of a wifi signal in an area, mapped by a vacuum cleaner.

FIG. 4 schematically shows a processing circuit adapted to implement the method for obtaining measurement data for a parameter, based on a sensor mounted on the vacuum cleaner, in order to establish a map of the area.

### DETAILED DESCRIPTION OF CERTAIN ILLUSTRATIVE EMBODIMENTS

A method for establishing a map of a parameter in an area is described below.

The method can be implemented by a robot type of device, i.e. a robot that can move autonomously within an area, such as a vacuum cleaner, a mower, a drone, or a guided autonomous vehicle. The robot can perform a first function, e.g. clean a building (in the case of a vacuum cleaner) or mow the lawn (in the case of a lawn mower).

The robot can further be configured to perform a second function that is distinct from the first function and establish a map of a parameter, on the basis of a sensor mounted on the robot. For example, while executing the first function, the robot can map a wifi signal strength, a temperature, a humidity level, a pressure, or a light intensity in the area.

In one non-limiting embodiment, a vacuum cleaner on which a wifi sensor is mounted is considered.

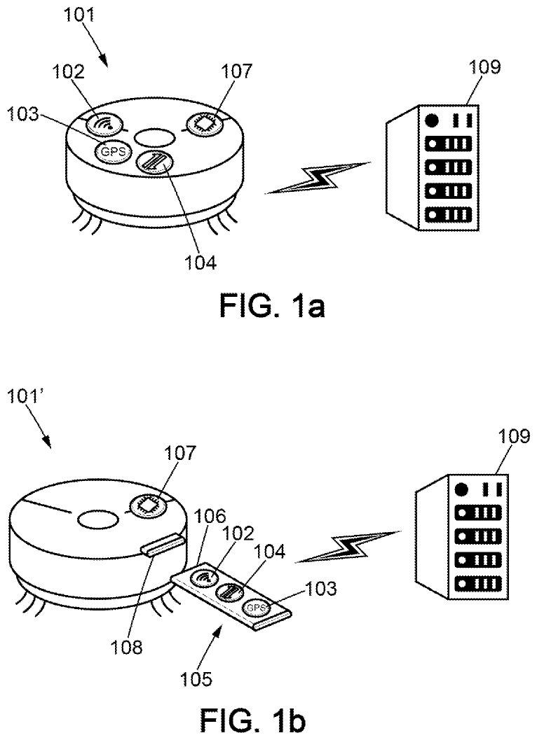

FIGS. 1a and 1b show two embodiments of a vacuum cleaner 101, 101′ configured to move autonomously within an area such as a room or a floor of a building, and to clean the area.

Vacuum cleaner 101, 101′ may comprise wheels enabling it to move about.

A processing circuit 107 integrated into vacuum cleaner 101, 101′ may comprise instructions relating to the area to be cleaned and relating to a cleaning program. For example, processing circuit 107 can indicate to vacuum cleaner 101, 101′ the path to follow within an area.

In addition, vacuum cleaner 101, 101′ may comprise a position sensor 103, for example a LIDAR sensor or a GPS sensor, enabling vacuum cleaner 101, 101′ to determine is location and to move about within a defined area. Position sensor 103 allows vacuum cleaner 101, 101′ to determine its current location, for example in relation to a reference point such as its charging point for which the location within the area is known.

Vacuum cleaner 101, 101′ may comprise a wifi sensor 102 which allows detecting the strength of a wifi signal propagated in the area.

In a first embodiment shown in FIG. la, a vacuum cleaner 101 which conventionally does not comprise a wifi sensor 102 can be arranged so that a wifi sensor 102 is integrated into vacuum cleaner 101.

Physical adaptation of vacuum cleaner 101 is not required when vacuum cleaner 101 already comprises a wifi sensor 102 that is capable of detecting the strength of a wifi signal. In this case, the adaptation of vacuum cleaner 101 is software in nature, so that vacuum cleaner 101 can use wifi sensor 102 and position sensor 103 to establish a map.

Wifi sensor 102 may be connected to processing circuit 107 of vacuum cleaner 101 and be controlled by processing circuit 107.

In a second embodiment shown in FIG. 1b, vacuum cleaner 101′ may comprise a reception interface 108 configured to receive a connection interface 106 of an expansion module 105. Thus, expansion module 105 can be plugged into vacuum cleaner 101′ and can be connected to processing circuit 107 of vacuum cleaner 101′.

Expansion module 105 may comprise a plurality of sensors and in particular a wifi sensor 102 able to detect the strength of a wifi signal. When vacuum cleaner 101′ is carrying out the first function, it can use wifi sensor 102 of expansion module 105 to establish a map.

The advantage of expansion module 105 lies in the fact that it is not necessary to adapt vacuum cleaner 101′ in a specific manner in order to establish a map, and the presence of a reception interface 108 for receiving an expansion module 105 is sufficient. Expansion module 105 can be connected to any type of robot which has a suitable reception interface 108. Thus, a single expansion module 105 can be used for different robots, and different types of parameters can be detected with a single expansion module 105 when expansion module 105 comprises suitable sensors.

In the two embodiments in FIGS. 1a and 1b, vacuum cleaner 101, 101′ further comprises an acquisition interface 104 configured to acquire topology data, for example a digital map of the area to be traveled which indicates the position of walls or other obstacles.

For example, acquisition interface 104 can acquire data from a pre-recorded digital map, in order to indicate to vacuum cleaner 101, 101′ the position of walls or furniture within the area.

Alternatively, vacuum cleaner 101. 101′ can move within the area without knowing the topology of the area, and acquisition interface 104 can acquire data relating to the topology during movement of vacuum cleaner 101, 101′. Indeed, position sensor 103 can comprise a collision sensor, and vacuum cleaner 101, 101′ can detect the presence of obstacles in the area and determine the distances traveled between obstacles.

The topology data acquired by acquisition interface 104 may be transmitted to processing circuit 107.

In the embodiment according to FIG. 1b, acquisition interface 104 as well as position sensor 103 may be located in expansion module 105.

The mapping data, i.e. the measured data for the parameter, may be saved in processing circuit 107, linked to the respective location of vacuum cleaner 101, 101′ at the time of the measurement.

Processing circuit 107 can transmit the mapping data after their acquisition, or gradually as the data are acquired, in order to process these data.

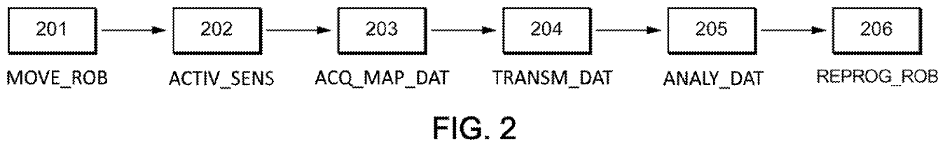

FIG. 2 shows a flowchart of a method for obtaining measurement data concerning wifi signal strength, based on wifi sensor 102 mounted on vacuum cleaner 101. 101′ as described in FIGS. 1a or 1b. The steps of the method are not necessarily implemented in the order indicated.

Vacuum cleaner 101, 101′ can move 201 about within an area, e.g. a room or building, in order to carry out its primary function, i.e. cleaning. The movement can take place according to the presence of obstacles in the area. For this purpose, data relating to the topology of the area can be acquired by acquisition interface 104 of vacuum cleaner 101, 101′, and vacuum cleaner 101, 101′ can move about autonomously on the basis of these data.

For example, vacuum cleaner 101, 101′ may use the data from a pre-recorded digital map, or may gradually determine during its movement the presence of obstacles in the area and the distances traveled between the obstacles.

Wifi sensor 102 may be activated 202 when vacuum cleaner 101, 101′ begins to move, or during movement and when vacuum cleaner 101, 101′ enters a defined area. Vacuum cleaner 101, 101′ can measure 203 values of the wifi signal strength while it is moving and can associate them with the location where the measurements were made.

The mapping data can be transmitted 204 via the acquisition interface 104 to a remote server 109, e.g. the smartphone of a user of vacuum cleaner 101, 101′, or a provider of vacuum cleaner 101, 101′, or a provider of the wifi signal.

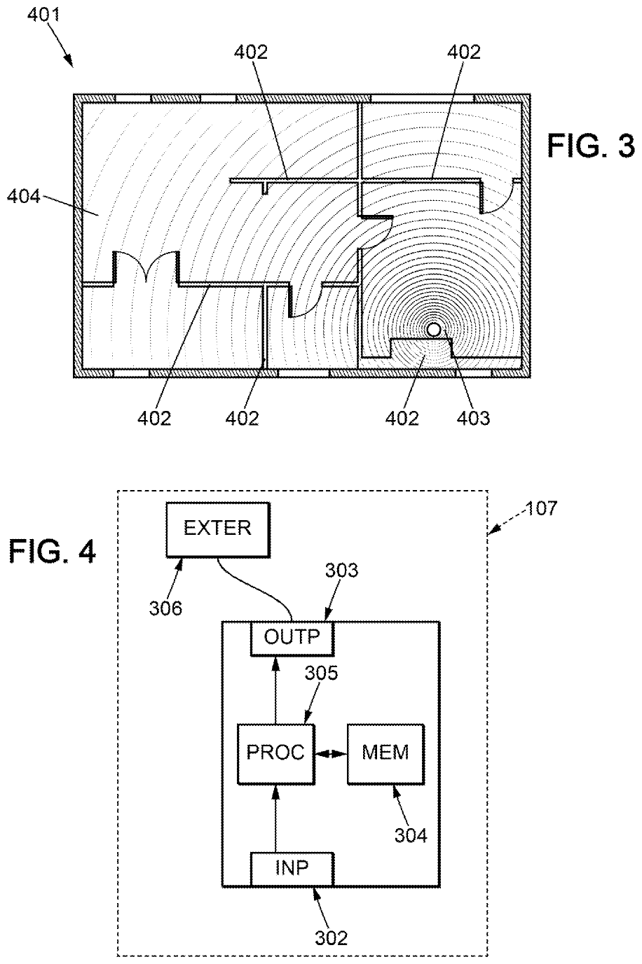

An example of a graphical representation of a map established on the basis of mapping data for an apartment in a specific timeframe and on the basis of the topology data for this apartment is shown in FIG. 3.

This map shows obstacles 402 present in the apartment, in particular walls and furniture. The distribution of the wifi signal strength is represented by lines for which the density varies according to the wifi signal strength. High wifi signal strength 403 can be viewed as a high line density, and low wifi signal strength 404 as a low line density. Another option would be to use shades of gray to represent the local strength of the wifi signal.

Regularity in the collection of measured data makes it possible to generate a time series of maps 401, which allows representing the variability of the wifi signal strength temporally and spatially.

Returning to the method according to FIG. 2, the information relating to map 401 can be analyzed 205 and used to solve a one-time or repetitive problem. In particular, map 401 according to FIG. 3 or a series of maps 401 can be used to provide corrective actions to the signal or obstacles in the area in order to improve the wifi signal strength.

A user can consult map 401 on a dedicated application on their smartphone. On the basis of map 401, the user can decide to move objects in his/her apartment in order to optimize the wifi signal strength in their apartment.

When the analysis of map 401 is carried out at the wifi signal provider, advice can be formulated and sent to the user, for example on the smartphone application. For example, the provider can indicate to the user a suitable location in their apartment for installing a wifi repeater or a home Internet hub.

According to another function, vacuum cleaner 101, 101′ can be reprogrammed 206 on the basis of map 401. This new function can be illustrated by the example of a vacuum cleaner 101, 101′ which is configured to establish, according to its second function, a map of the humidity level in an apartment.

Previously established maps of the humidity level may reveal that the humidity level varies in the apartment from room to room and according to the time of day. On the basis of this knowledge deduced from the maps, vacuum cleaner 101, 101′ can be reprogrammed to implement its first function when the humidity level in the apartment is at its lowest, in order to avoid ruining vacuum cleaner 101, 101′, for a more sustainable use of vacuum cleaner 101, 101′. Furthermore, the storage location for vacuum cleaner 101, 101′ when it is not in use can be determined based on the humidity level map established by vacuum cleaner 101, 101′.

In an example not shown in the figures, a robot can comprise two sensors and thus establish a map of two parameters.

For example, a vacuum cleaner can comprise a wifi sensor and a temperature sensor (often present in batteries), enabling the wifi signal strength to be analyzed as a function of the temperature.

It may turn out that the wifi signal strength depends on the temperature, and actions influencing the temperature can be taken (e.g. closing a door to an apartment in summer), for the purposes of optimizing the wifi signal strength.

In another example not shown in the figures, a vacuum cleaner can comprise a temperature sensor and a pressure sensor. The temperature sensor may detect, at a given location and during a predetermined time interval, a temperature decrease. The pressure sensor may measure the pressure at the same location and during the same time interval. The measurement of the temperature and the pressure may be iterated, during successive predetermined time steps. Thus, the temperature and pressure variations may be determined as a function of time, and the origin of the variations of temperature/pressure may be identified. For example, it may be possible to determine whether a window has been opened (causing a pressure variation) or not.

In another example not shown in the figures, the vacuum cleaner comprises a temperature sensor, a humidity sensor and a light sensor. The temperature sensor may detect, at a given location and during a predetermined time interval, a temperature decrease.

The humidity sensor may measure a humidity level and the light sensor may measure the light intensity at the same location and during the same time interval.

The measurement of the temperature, the humidity level and the light intensity may be iterated, during successive predetermined time intervals. Thus, the variations of temperature, humidity level and light intensity may be determined as a function of time, and the origin of the variations of temperature/ of humidity level/of light intensity may be identified. For example, it may be determined whether the door of a refrigerator illuminated from the inside has been opened (causing an increase of the humidity level and of the light intensity) or not.

FIG. 4 shows an embodiment of processing circuit 107 configured to implement at least part of the method described in relation to FIG. 2.

Processing circuit 107 comprises at least one input interface 302 for receiving messages or instructions, and at least one output interface 303 for communicating with external devices 306 such as expansion module 105 or remote server 109.

The at least one input interface 302 can be configured to receive instructions relating to the execution of the first function and the second function.

Processing circuit 107 further comprises a memory 304 for storing instructions enabling the implementation of at least part of the method, the data received, and temporary data for carrying out the various steps and operations of the method as described above.

Processing circuit 107 may further comprise a control circuit, for example:
a processor able to interpret instructions in the form of a computer program, or
a circuit board in which the steps of the disclosed method are described in the silicon, or
a programmable electronic chip such an FPGA chip (“Field-Programmable Gate Array”), an SOC (“System On Chip”), or an ASIC (“Application Specific Integrated Circuit”).

SOCs or systems on a chip are embedded systems that integrate all the components of an electronic system into a single chip. An ASIC is a specialized electronic circuit that groups customized functionalities for a given application. ASICs are generally configured during their manufacture and can only be simulated by an operator of processing circuit 107. FPGA-type programmable logic circuits are electronic circuits that are reconfigurable by the operator of processing circuit 107.

Processing circuit 107 may be a computer, an electronic component, or another device comprising a processor operably coupled to a memory, as well as, depending on the chosen embodiment, a data storage unit, and other associated hardware elements such as a network interface and a media reader for reading removable storage media and for writing to such media, which are not shown in FIG. 4.

Depending on the embodiment, memory 304, the data storage unit, or the removable storage medium contain instructions which, when executed by control circuit 305, cause this circuit to carry out or control the at least one input interface 302, the at least one output interface 303, the storage of data in memory 304, and/or the processing of data and/or the implementation of at least part of the method according to FIG. 2. Control circuit 305 may be a component which implements the control of processing circuit 107.

In addition, processing circuit 107 may be implemented in software form, in which case it takes the form of a program executable by a processor, or in hardware form, such as an application specific integrated circuit ASIC, a system on chip SOC, or in the form of a combination of hardware and software elements, for example a software program intended to be loaded and executed on an electronic component described above such as an FPGA, processor.

Processing circuit 107 may also use hybrid architectures, for example architectures based on a CPU+FPGA, a GPU (“Graphics Processing Unit”), or an MPPA (“Multi-Purpose Processor Array”).

This disclosure makes it possible to establish a map of a parameter in an area, by a sensor mounted on a robot type of device.

This disclosure is not limited to the example devices, systems, methods, uses, and computer program products described above solely by way of example, but encompasses all variants conceivable to the person skilled in the art within the framework of the protection sought.

1. A method of obtaining measurement data for at least one parameter, based on at least one sensor, wherein the sensor is mounted on a robot type of device capable of moving within an area in order to carry out a first function, the method comprising:
activating the sensor in order to measure the parameter at least during a movement of the device within the area, and
acquiring data, in a second function of the device that is distinct from the first function, in order to establish a map of the parameter in the area.

2. The method according to claim 1, wherein the sensor is activated to measure the parameter while the device is moving about within the area to carry out the first function.

3. The method according to claim 1, wherein the parameter is one among: at least one wifi signal strength, a temperature, a humidity level, a pressure, and a light intensity.

4. The method according to claim 1, wherein the acquisition of data in order to establish the map of the parameter uses topology data for the area from a previously saved digital map corresponding to a topology of the area.

5. The method according to claim 1, comprising a measurement of topology data for the area by determining distances traveled by the device between obstacles present in the area, in order to obtain a digital map of the area.

6. The method according to claim 4, wherein the device is reprogrammed to use the topology data for the area, for the purposes of a new function in the implementation of the first function.

7. The method according to claim 1, wherein at least two sensors are mounted on the robot type of device, the method comprising:
activating a first sensor mounted on the robot type of device for measuring a first parameter at a given location of the robot type of device during a predetermined time interval;
activating a second sensor distinct from the first sensor and mounted on the robot type of device for measuring a second parameter at the location of the robot type of device during the predetermined time interval; and
iterating the measurement of the first parameter and the second parameter, and determining an occurrence of an event or an absence of the event in the area, based on the measurements of the first parameter and the second parameter.

8. The method according to claim 7, wherein at least three sensors are mounted on the robot type of device, the method further comprising:
activating a third sensor distinct from the first sensor and the second sensor and mounted on the robot type of device for measuring a third parameter at the location of the robot type of device during the predetermined time interval; and
iterating the measurement of the first parameter, the second parameter and the third parameter, and determining an occurrence of an event or an absence of the event in the area, based on the measurements of the first parameter, the second parameter and the third parameter.

9. A processing circuit comprising a processor and a memory, the memory storing program code instructions of a computer program which, when these program code instructions are executed by the processing circuit, cause the processing circuit to implement the method according to claim 1.

10. A robot type of device, capable of moving within an area in order to carry out a first function, to obtain measurement data for at least one parameter, the device comprising a processing circuit configured to implement the method according to claim 1.

11. The device according to claim 10, further comprising an expansion module connected to the processing circuit and comprising:
at least one sensor configured to be activated and to measure the parameter at least during a movement of the device within the area; and
an acquisition interface configured to acquire data, according to the second function of the device, in order to establish a map of the parameter in the area.

12. The device according to claim 11, wherein the expansion module further comprises a position sensor configured to determine a location of the device when moving about within the area.

13. An expansion module configured to be connected to a processing circuit of a device able to move about within an area in order to carry out a first function, the expansion module comprising:
a connection interface configured to connect the expansion module to the processing circuit of the device;
at least one sensor configured to be activated and to measure at least one parameter during a movement of the device within the area; and
an acquisition interface configured to acquire data, according to a second function of the device that is distinct from the first function, in order to establish a map of the parameter in the area.

14. The expansion module according to claim 13, wherein the data acquisition interface is connected to a remote server and is configured to transmit the acquired data to the remote server.

15. The expansion module according to claim 13, wherein the data acquisition interface is connected to the processing circuit of the device in order to send mapping data for the parameter to the processing circuit, the processing circuit being programmed to be configured to use the mapping data in performing the first function.
